(19) United States
(12) Patent Application Publication
(10) Pub. No.: US 2018/0287038 A1
(43) Pub. Date: Oct. 4, 2018

(54) THERMOELECTRIC CONVERSION DEVICE

(71) Applicant: TDK CORPORATION, Tokyo (JP)

(72) Inventors: Kazuya MAEKAWA, Tokyo (JP); Makoto SHIBATA, Tokyo (JP)

(73) Assignee: TDK CORPORATION, Tokyo (JP)

(21) Appl. No.: 15/925,295

(22) Filed: Mar. 19, 2018

(30) Foreign Application Priority Data
Mar. 28, 2017 (JP) 2017-062782
Dec. 15, 2017 (JP) 2017-241090

(51) Int. Cl. H01L 35/32; H01L 35/30; H01L 27/16; H01L 27/142

(52) U.S. Cl. CPC H01L 35/32; H01L 27/142; H01L 27/16; H01L 35/30

(57) ABSTRACT

A thermoelectric conversion device includes: a base material; a thermoelectric conversion element in which an N-type semiconductor layer and a P-type semiconductor layer are stacked on a first surface side of the base material with insulating layers therebetween; and a heat transfer part thermally joined to the base material and passing through the thermoelectric conversion element in a thickness direction of the thermoelectric conversion element, wherein first end sides of the N-type semiconductor layers and the P-type semiconductor layers are thermally joined to the heat transfer part on a side of the thermoelectric conversion element facing the heat transfer part in a state where the N-type semiconductor layer and the P-type semiconductor layer are electrically insulated from the heat transfer part.

### BACKGROUND

The present invention relates to a thermoelectric conversion device.

Priority is claimed on Japanese Patent Application No. 2017-062782 filed on Mar. 28, 2017, and Japanese Patent Application No. 2017-241090 filed on Dec. 15, 2017, the contents of which are incorporated herein by reference.

In recent years, applications of thermoelectric conversion elements (thermoelectric conversion devices) using thermoelectric characteristics of materials have been researched. To be specific, application of thermoelectric conversion elements using the Seebeck effect to, for example, power generation elements using temperature differences between the outside air and the human body, and power generation elements using exhaust heat from vehicles, incinerators, heating appliances, or the like have been researched. On the other hand, application of thermoelectric conversion elements using the Peltier effect in, for example, cooling elements for central processing units (CPUs) or laser media have been researched. Among these, particularly, attention has been paid to application of thermoelectric conversion elements to power generation elements as elements for energy harvesting.

For example, the thermoelectric conversion element disclosed in Japanese Unexamined Patent Application, First Publication No. 2013-21089 has a structure in which a thermoelectric conversion material layer is stacked above a substrate with a buffer layer therebetween. Furthermore, each thermoelectric conversion material layer has a structure in which an N-type semiconductor layer and a P-type semiconductor layer are stacked with an insulating layer therebetween. In addition, one electrode layer configured to electrically connect one end sides of the N-type semiconductor layer and the P-type semiconductor layer, which are adjacent to each other and sandwich the insulating layer, is provided on one side end surface of each thermoelectric conversion material layer. On the other hand, another electrode layer configured to electrically connect the other end side of a P-type semiconductor layer of the first thermoelectric conversion material layer and the other end side of an N-type semiconductor layer of the second thermoelectric conversion material layer which are adjacent to each other in a thickness direction of the thermoelectric conversion element is provided on the other side end surface of each thermoelectric conversion material layer.

In the thermoelectric conversion element having the above-described structure, temperatures of one end side of each P-type semiconductor layer and each N-type semiconductor layer become relatively higher due to heat transferred from a heat source to the one end side of each P-type semiconductor layer and each N-type semiconductor layer. On the other hand, since heat transferred to each P-type semiconductor layer and each N-type semiconductor layer is radiated from the other end side of each P-type semiconductor layer and each N-type semiconductor layer to the outside, temperatures of the other end side of each P-type semiconductor layer and each N-type semiconductor layer become relatively lower. Therefore, since temperature differences are generated between one end side and the other end side of each P-type semiconductor layer and each N-type semiconductor layer, an electromotive force due to the Seebeck effect can be obtained.

Here, in the thermoelectric conversion element disclosed in Japanese Unexamined Patent Application, First Publication No. 2013-21089, in order to efficiently use heat from the heat source, it is necessary to concentrate heat from the heat source to a side end surface of each thermoelectric conversion material layer on one end side thereof.

However, in the thermoelectric conversion element disclosed in Japanese Unexamined Patent Application, First Publication No. 2013-21089, since an area of the side end surface of each thermoelectric conversion material layer is small, it is difficult to concentrate heat from the heat source to the side end surface of each thermoelectric conversion material layer and efficiently transfer the heat to the one end side of each P-type semiconductor layer and each N-type semiconductor layer. Therefore, there is a concern concerning heat from the heat source which cannot be efficiently used.

### SUMMARY

It is desirable to provide a thermoelectric conversion device capable of efficiently transferring heat from a heat source to one end sides (first end sides) of a P-type semiconductor layer and an N-type semiconductor layer.

A thermoelectric conversion device includes: a base material; a thermoelectric conversion element in which an N-type semiconductor layer and a P-type semiconductor layer are stacked on a first surface side of the base material with an insulating layer therebetween; and a heat transfer part thermally joined to the base material and passing through the thermoelectric conversion element in a thickness direction of the thermoelectric conversion element, wherein first end sides of the N-type semiconductor layer and the P-type semiconductor layer are thermally joined to the heat transfer part on a side of the thermoelectric conversion element facing the heat transfer part in a state where the N-type semiconductor layer and the P-type semiconductor layer are electrically insulated from the heat transfer part.

### BRIEF DESCRIPTION OF THE DRAWINGS

FIG. 1 is a cross-sectional view showing a schematic constitution of a thermoelectric conversion device according to a first embodiment of the disclosure.

FIGS. 2a and 2b are plan views illustrating each of constitutions of a heat transfer part included in the thermoelectric conversion device shown in FIG. 1.

FIG. 3 is a cross-sectional view showing a schematic constitution of a thermoelectric conversion device according to a second embodiment of the disclosure.

FIG. 4 is a cross-sectional view showing a schematic constitution of a thermoelectric conversion device according to a third embodiment of the disclosure.

FIG. 5 is a cross-sectional view showing a schematic constitution of a thermoelectric conversion device according to a fourth embodiment of the disclosure.

FIG. 6 is a cross-sectional view illustrating a modification of the thermoelectric conversion device shown in FIG. 1.

FIG. 7 is a cross-sectional view illustrating a modification of the thermoelectric conversion device shown in FIG. 1.

### DETAILED DESCRIPTION

Embodiments of the disclosure will be described in detail below with reference to the drawings.

Note that, in the drawings used in the following description, the characteristic parts are shown in an enlarged manner in some cases for the sake of convenience to express the characteristics in an easily understandable way, and dimensional ratios or the like between each of constituent elements are not necessarily the same as the actual ones. Furthermore, materials and the like illustrated in the following description are merely examples, and the present invention is not limited thereto. In addition, the disclosure can be implemented with appropriate modifications within the scope.

### First Embodiment

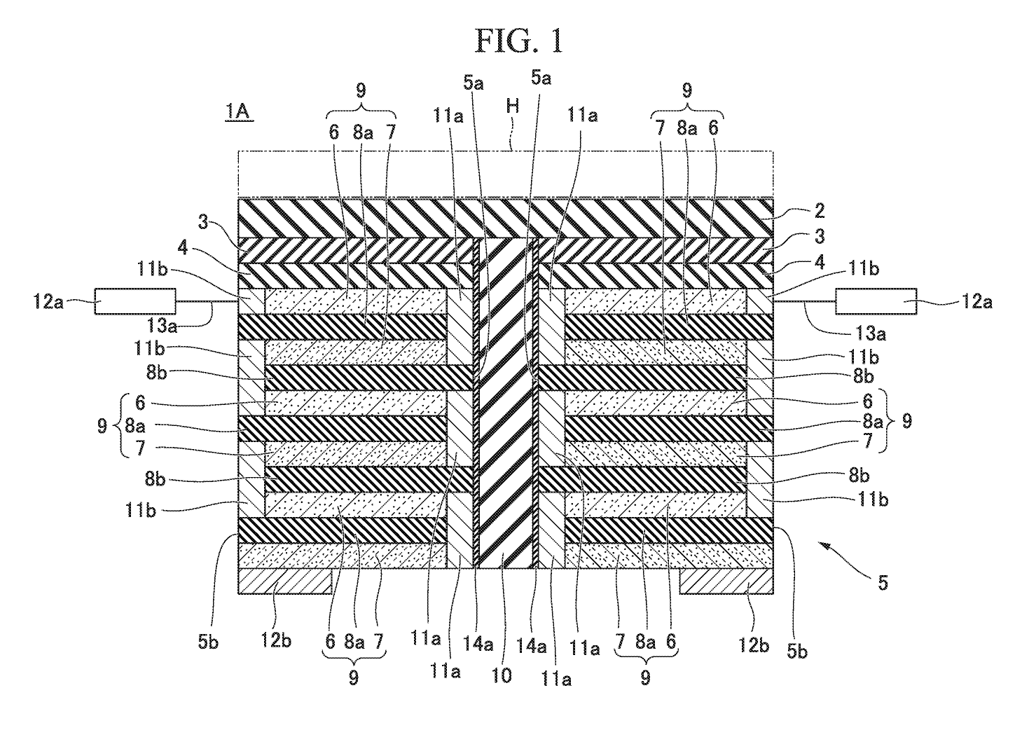

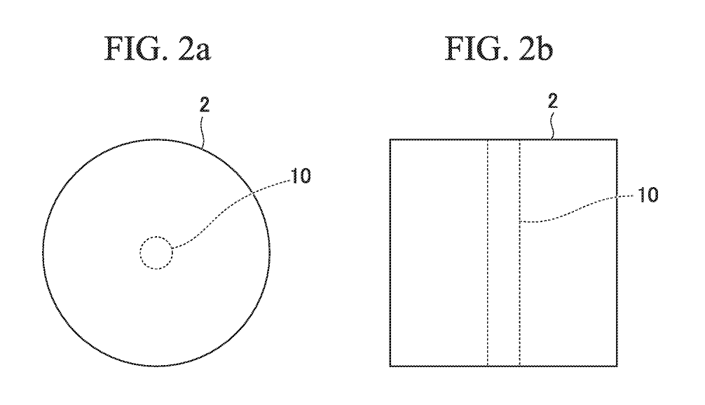

First, as a first embodiment of the disclosure, for example, a thermoelectric conversion device 1A illustrated in FIGS. 1 and 2 will be described. Note that FIG. 1 is a cross-sectional view showing a schematic constitution of the thermoelectric conversion device 1A. FIGS. 2a and 2b are plan views illustrating each of constitutions of a heat transfer part 10 included in the thermoelectric conversion device 1A.

As illustrated in FIG. 1, the thermoelectric conversion device 1A in the embodiment has a structure in which a thermoelectric conversion element 5 is arranged on the first surface side of a substrate 2 with a first buffer layer 3 and a second buffer layer 4 therebetween. Furthermore, the thermoelectric conversion element 5 has a structure in which N-type semiconductor layers 6 and P-type semiconductor layers 7 are repeatedly stacked with insulating layer 8a and 8b therebetween. In other words, the thermoelectric conversion element 5 has a structure in which a plurality of (three in the embodiment) thermoelectric conversion material layers 9 in which an N-type semiconductor layer 6 and a P-type semiconductor layer 7 are stacked with an insulating layer 8a are stacked with a insulating layer 8b therebetween.

Note that the thermoelectric conversion element 5 is not necessarily limited to having the above structure in which a plurality of thermoelectric conversion material layers 9 are stacked and a constitution in which at least one or more thermoelectric conversion material layers 9 are provided may be adopted.

The substrate 2 is made of a flat-plate-like base material. Examples of the base material include silicon (Si), magnesium oxide (MgO), strontium titanate (SrTiO₃), barium titanate (SrTiO₃), or the like.

As well as having a function of being a buffer layer conventionally used in the semiconductor field, the first buffer layer 3 and the second buffer layer 4 have a function of, when a heat source H is arranged on an opposite side (the other surface side) to a side (the first surface side) on which the thermoelectric conversion element 5 of the substrate 2 is arranged, blocking (insulating from) heat transferred from the heat source H to the substrate 2 between the substrate 2 and the thermoelectric conversion element 5.

Also, at least one of the first buffer layer 3 and the second buffer layer 4 preferably has insulating properties. Thus, an electrical short circuit can be prevented from occurring between the substrate 2 and the thermoelectric conversion element 5.

In the embodiment, for example, a constitution in which a Si substrate is used as the substrate 2, zirconia (ZrO₂) or stabilized zirconia (YSZ) is used as the first buffer layer 3, and strontium titanate (SrTiO₃) or barium titanate (SrTiO₃) is used as the second buffer layer 4 can be provided.

In the case of such a constitution, for example, it is possible to appropriately use a semiconductor oxide with a perovskite structure such as strontium niobium titanate (Sr(Ti,Nb)O₃), nickel oxide (Ni₉₀Li₁₀₀) or tin oxide (SnO) doped with lithium (Li), and an oxide with a perovskite structure such as SrTiO₃ or SrTiO₃ for the N-type semiconductor layers 6, the P-type semiconductor layers 7, and the insulating layers 8a and 8b, respectively.

With such a constitution, a thin film of a semiconductor material formed above the substrate 2 can be epitaxially grown and thermoelectric characteristics (amount of electric power generation) of the thermoelectric conversion element 5 can be improved. Furthermore, the thermoelectric conversion element 5 which is also resistant to a high temperature environment can be formed.

In addition, when strontium titanate (SrTiO₃) or barium titanate (SrTiO₃) is provided between the first buffer layer 3 and the thermoelectric conversion element 5 for the second buffer layer 4, a thin film of a semiconductor material formed above the substrate 2 can be epitaxially grown into a C-axis orientation represented as (00k). Thus, thermoelectric characteristics (amount of electric power generation) of the thermoelectric conversion element 5 can be further improved.

Also, in the embodiment, for example, a constitution in which a Si substrate, SiO2, and a high resistance Si with a specific resistance of 10 Ω·cm or more are used for the substrate 2, the first buffer layer 3, and the second buffer layer 4, respectively, can be provided.

In the case of such a constitution, for example, a multilayer film including an N type silicon (Si) film and an N type silicon germanium (SiGe) alloy film which are doped with antimony (Sb) at a high concentration (10¹⁸ to 10¹⁹ cm⁻³), a multilayer film including a P type silicon (Si) film and P type silicon germanium (SiGe) alloy film which are doped with, for example, boron (B) at (10¹⁸ to 10¹⁹ cm⁻³), and a high resistance silicon (Si) with a specific resistance of 10 Ω·cm or more can be appropriately used as the N-type semiconductor layers 6, the P-type semiconductor layers 7, and the insulating layers 8a and 8b, respectively.

With such a constitution, thermoelectric characteristics (amount of electric power generation) of the thermoelectric conversion element 5 can be further improved. Furthermore, in the case of such a constitution, a part from the substrate 2 to the first buffer layer 3 and the second buffer layer 4 can be formed using a silicon on insulator (SOI) substrate.

Note that the N-type semiconductor layers 6 and the P-type semiconductor layers 7 are not necessarily limited to the above-described constitution including the multilayer film when the N-type semiconductor layers 6 and the P-type semiconductor layers 7 are configured to include Si and SiGe and may be single layer films. Furthermore, the thermoelectric conversion element 5 is not limited to the above thin film formed above the surface of the substrate 2 and may be formed using a thin film obtained using a bulk.

The thermoelectric conversion device 1A according to the embodiment includes the heat transfer part 10 thermally joined to the substrate 2 in a state where the thermoelectric conversion device 1A passes through the thermoelectric conversion element 5 in a thickness direction of the thermoelectric conversion element.

It is desirable that the heat transfer part 10 have a thermal conductivity higher than the thermal conductivity of the above-described first buffer layer 3 and it is desirable that the heat transfer part 10 have a thermal conductivity higher than the thermal conductivity of the above-described second buffer layer 4. To be specific, it is desirable that the heat transfer part 10 be formed using a material with a thermal conductivity of 160 W/m·K or more. As such a material, for example, a metal such as aluminum (Al) and copper (Cu), silicon (Si), or the like can be used.

The heat transfer part 10 may have, for example, a cylindrical shape illustrated in FIG. 2a and can be configured to be provided in a state where the heat transfer part 10 passes through the thermoelectric conversion element 5 at a center part of the inside of the thermoelectric conversion element 5 having a substantially annular shape in a plan view. In other words, the periphery of the heat transfer part 10 illustrated in FIG. 2a is surrounded by the thermoelectric conversion element 5 in a plan view.

On the other hand, the heat transfer part 10 may have, for example, a rectangular flat plate shape illustrated in FIG. 2b and can be configured to be provided having a substantially rectangular shape in a plan view dividing the thermoelectric conversion element 5 at a central portion. In other words, both sides of the heat transfer part 10 illustrated in FIG. 2b are surrounded by the thermoelectric conversion element 5 in a plan view.

Note that the heat transfer part 10 illustrated in FIG. 2a is not limited to a solid shape such as the above-described cylindrical shape and can also be configured to have a hollow shape such as a cylindrical shape in which the heat transfer part 10 surrounds the periphery of a hole passing through the thermoelectric conversion element 5 in a thickness direction of the thermoelectric conversion element.

As illustrated in FIG. 1, the thermoelectric conversion element 5 includes a hot junction side electrode 11a configured to electrically connect the first end sides (one end sides) of the N-type semiconductor layers 6 and the P-type semiconductor layers 7, which are adjacent to each other and sandwich the insulating layer 8a, on a side of the thermoelectric conversion element 5 facing the heat transfer part 10 and a cold junction side electrode 11b configured to electrically connect the second end sides (other end sides) of the N-type semiconductor layers 6 and the P-type semiconductor layers 7, which are adjacent to each other and sandwich the insulating layer 8b, on a side of the thermoelectric conversion element 5 opposite to the side thereof facing the heat transfer part 10.

Also, the hot junction side electrode 11 a is provided along side end surfaces of the N-type semiconductor layers 6, the insulating layer 8a, and the P-type semiconductor layers 7 on the first end side of the N-type semiconductor layers 6 and the first end side of the P-type semiconductor layers 7, which are adjacent to each other and sandwich the insulating layer 8a. On the other hand, the cold junction side electrode 11b is provided along side end surfaces of the N-type semiconductor layers 6, the insulating layer 8b, and the P-type semiconductor layers 7 on the second end side of the N-type semiconductor layers 6 and the second end side of the P-type semiconductor layers 7, which are adjacent to each other and sandwich the insulating layer 8b.

It is desirable to use a metal for materials of the hot junction side electrode 11a and the cold junction side electrode 11b. Among these, particularly, for example, aluminum (Al), copper (Cu), titanium (Ti), gold (Au), platinum (Pt), silver (Ag), nickel (Ni), chromium (Cr), or the like which have a high conductivity and thermal conductivity and which can be easily shaped can be appropriately used.

In the thermoelectric conversion device 1A according to the embodiment, the hot junction side electrode 11a and the cold junction side electrode 11b are arranged to be alternately shifted in a thickness direction of the thermoelectric conversion element 5. Thus, the N-type semiconductor layers 6 and the P-type semiconductor layers 7 repeatedly stacked with the insulating layers 8a and 8b therebetween are configured to be alternately connected in series.

Note that, in the thermoelectric conversion element 5 according to the embodiment, a cold junction side electrode 11b located closest to the substrate 2 is configured to be connected to only an N-type semiconductor layers 6 adjacent to the second buffer layer 4 in view of its structure.

The thermoelectric conversion device 1A according to the embodiment includes first extraction electrode 12a electrically connected to the first semiconductor layer (the N-type semiconductor layer 6 in the embodiment) located closest to the substrate 2 and the second extraction electrode 12b electrically connected to the second semiconductor layer (the P-type semiconductor layer 7 in the embodiment) located farthest from the substrate 2 among the N-type semiconductor layers 6 and the P-type semiconductor layers 7 constituting the thermoelectric conversion element 5.

The first extraction electrode 12a is located outward from an end (hereinafter referred to as an “inner end surface 5b”) of the thermoelectric conversion element 5 on a side opposite to the end (hereinafter referred to as an “inner end surface 5a”) of the thermoelectric conversion element 5 facing the heat transfer part 10 and is electrically connected to the cold junction side electrode 11b adjacent to the above-described second buffer layer 4 and the N-type semiconductor layers 6 with a wiring 13a leading to the outside therebetween.

The second extraction electrode 12b is provided at a position along an outer end surface 5b of the thermoelectric conversion element 5 while in contact with a surface of the P-type semiconductor layer 7 opposite to a surface of the P-type semiconductor layer 7 facing the insulating layer 8a.

In the thermoelectric conversion element 5, the N-type semiconductor layers 6 and the P-type semiconductor layers 7 are alternately connected in series between the extraction electrodes 12a and 12b with the hot junction side electrode 11a and the cold junction side electrode 11b therebetween.

In the thermoelectric conversion device 1A according to the embodiment, the first end sides of the N-type semiconductor layers 6 and the P-type semiconductor layers 7 are thermally joined to the heat transfer part 10 on a side of the thermoelectric conversion element 5 facing the heat transfer part 10 in a state where the heat transfer part 10 is electrically insulated from the N-type semiconductor layers 6, the P-type semiconductor layers 7, and the hot junction side electrode 11a with an insulating layer 14a therebetween.

The insulating layer 14a is arranged along an inner end surface 5a of the thermoelectric conversion element 5. In terms of the material of the insulating layer 14a, it is desirable to use a material having high thermal conductivity and capable of electrically insulating the heat transfer part 10 from the N-type semiconductor layers 6, the P-type semiconductor layers 7, and the hot junction side electrode 11a. Examples of such a material can include aluminum oxide (Al₂O₃), aluminum nitride (AlN), or the like. It is desirable that the insulating layer 14a be formed as thin as possible in view of heat conductivity.

Note that, when the heat transfer part 10 itself has insulating properties, the heat transfer part 10 may be configured to directly be joined to the hot junction side electrode 11a without involving the above-described insulating layer 14a. In other words, when the heat transfer part 10 has insulating properties, it is also possible to omit the insulating layer 14a.

In the thermoelectric conversion device 1A having the above-described constitution, the heat source H is arranged on the other surface side of the substrate 2 so that heat transferred from the heat source H to the substrate 2 is transferred from the heat transfer part 10 to first end side (hot junction side electrode 11a side) of each of the N-type semiconductor layers 6 and the P-type semiconductor layers 7. Thus, a temperature on the first end side of each of the N-type semiconductor layers 6 and the P-type semiconductor layers 7 becomes relatively high.

On the other hand, since heat transferred to each of the N-type semiconductor layers 6 and the P-type semiconductor layers 7 is radiated from the second end side thereof (the side facing the cold junction side electrode 11b and opposite to the side facing the heat transfer part) to the outside, a temperature of the second end side of each of the N-type semiconductor layers 6 and the P-type semiconductor layers 7 becomes relatively low.

Therefore, a temperature difference occurs between: the first end sides (the side facing the hot junction side electrode 11a and the heat transfer part) of each of the N-type semiconductor layers 6 and the P-type semiconductor layers 7; and the second end sides thereof (the side facing the cold junction side electrode 11b and opposite to the side facing to the heat transfer part). Thus, charge (carriers) moves between the hot junction side electrode 11a side and the cold junction side electrode 11b side of each of the thermoelectric conversion material layers 9.

In other words, an electromotive force (voltage) due to the Seebeck effect is generated between the hot junction side electrode 11 a and the cold junction side electrode 11b. Therefore, a current flows from the cold junction side electrode 11b toward the hot junction side electrode 11a in the N-type semiconductor layers 6 of the N-type semiconductor layer 6 and the P-type semiconductor layer 7 constituting each of the thermoelectric conversion material layers 9. On the other hand, a current flows from the hot junction side electrode 11a toward the cold junction side electrode 11b in the P-type semiconductor layer 7.

Therefore, in the thermoelectric conversion device 1A, a direction of a current flowing in the N-type semiconductor layer 6 and a direction of a current flowing in the P-type semiconductor layer 7 are aligned in a direction in which the N-type semiconductor layers 6 and the P-type semiconductor layers 7 are alternately connected in series between first extraction electrode 12a and the second extraction electrode 12b.

Here, although an electromotive force generated in the first thermoelectric conversion material layer 9 (an N-type semiconductor layers 6 and a P-type semiconductor layers 7) is small, a plurality of thermoelectric conversion material layers 9 are connected in series between the first extraction electrode 12a and the second extraction electrode 12b. Therefore, relatively high power can be extracted as a total of electromotive forces from between the extraction electrodes 12a and 12b

Meanwhile, in the thermoelectric conversion device 1A according to the embodiment, the heat transfer part 10 thermally joined to the above-described substrate 2 is provided in a state where the heat transfer part 10 passes through the thermoelectric conversion element 5 in the thickness direction. Since an area of a substrate surface of the substrate 2 is large, much heat can be transferred from the heat source H to the heat transfer part 10.

Therefore, in the thermoelectric conversion device 1A according to the embodiment, heat transferred from the heat source H to the substrate 2 can be efficiently transferred from the heat transfer part 10 to the first end side (the side of the hot junction side electrode 11a) of each of the N-type semiconductor layers 6 and the P-type semiconductor layers 7.

### Second Embodiment

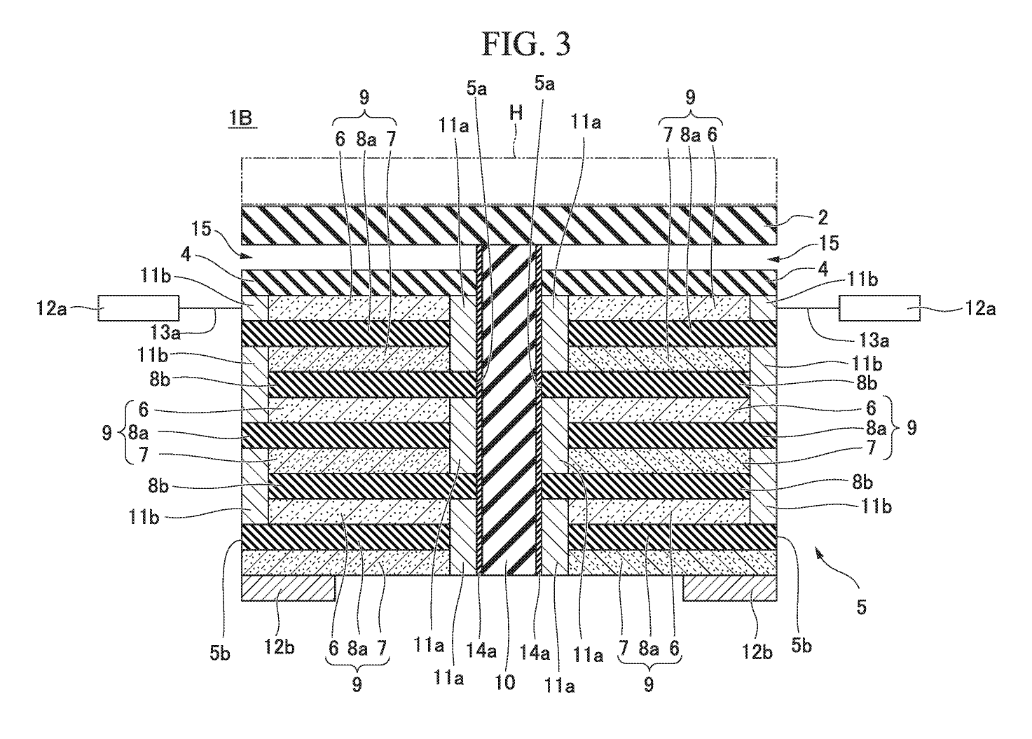

For example, a thermoelectric conversion device 1B illustrated in FIG. 3 will be described below as a second embodiment of the disclosure. Note that FIG. 3 is a cross-sectional view showing a schematic constitution of the thermoelectric conversion device 1B. Furthermore, in the following description, constituent elements that are the same as those of the above-described thermoelectric conversion device 1A will be omitted and will be denoted with the same reference numerals in the drawings.

As illustrated in FIG. 3, the thermoelectric conversion device 1B according to this embodiment is configured to include an air layer 15 instead of the first buffer layer 3 included in the thermoelectric conversion device 1A according to the above-described first embodiment. The air layer 15 is a gap provided between a substrate 2 and a second buffer layer 4 (thermoelectric conversion element 5). The air layer 15 can be formed, for example, by removing SiO₂ (sacrificial layer) of which a first buffer layer 3 is formed using wet etching (or dry etching may be used).

In the case of such a constitution, since a heat transfer part 10 has a thermal conductivity higher than the thermal conductivity of the air layer 15, heat transferred from a heat source H to the substrate 2 can be efficiently transferred from the heat transfer part 10 to the first end side (the side facing the hot junction side electrode 11a and the heat transfer part)) of each N-type semiconductor layer 6 and each P-type semiconductor layer 7. Furthermore, heat transferred from the heat source H to the substrate 2 can be blocked (insulated from) between the substrate 2 and the thermoelectric conversion element 5 through the air layer 15.

Therefore, in the thermoelectric conversion device 1B according to this embodiment, a large temperature difference (electromotive force) can be generated between the first end side (the side facing the hot junction side electrode 11a and the heat transfer part) and the second end side (the side facing the cold junction side electrode 11b and opposite to the side facing to the heat transfer part) of each of the N-type semiconductor layers 6 and the P-type semiconductor layers 7. As a result, it is possible to improve an output in the thermoelectric conversion device 1B.

Note that the air layer 15 is not limited to the above-described air layer formed by removing the entire SiO₂ (sacrificial layer) forming the first buffer layer 3 and may be formed by removing a part thereof. In this case, the air layer 15 does not particularly affect heat transfer characteristics of the heat transfer part 10 even if a part of SiO₂ remains around the heat transfer part 10.

### Third Embodiment

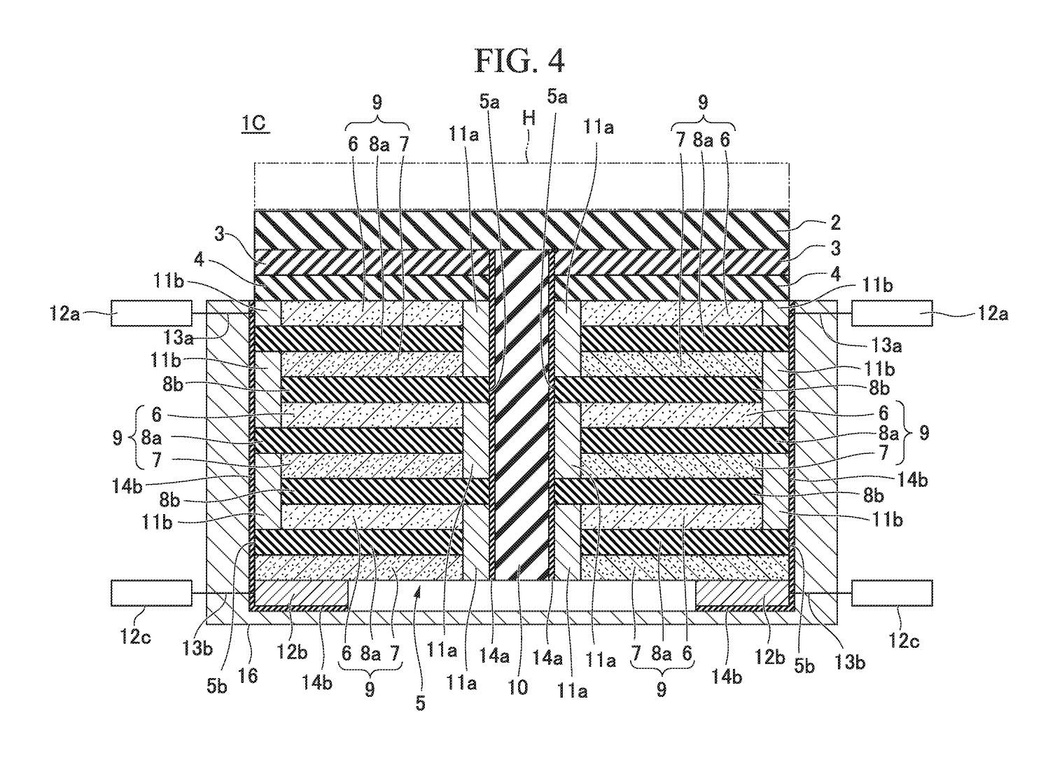

For example, a thermoelectric conversion device 1C illustrated in FIG. 4 will be described below as a third embodiment of the disclosure. Note that FIG. 4 is a cross-sectional view showing a schematic constitution of the thermoelectric conversion device 1C. Furthermore, in the following description, constituent elements that are the same as those of the above-described thermoelectric conversion device 1A will be omitted and will be denoted with the same reference numerals in the drawings.

As illustrated in FIG. 4, the thermoelectric conversion device 1C according to this embodiment is configured to include a heat transfer component 16 thermally joined to a cold junction side electrode 11b in addition to the above-described constitution of the thermoelectric conversion device 1A. Note that, although a case in which the heat transfer component 16 is added to the above-described constitution of the thermoelectric conversion device 1A has been exemplified in the embodiment, a constitution in which the heat transfer component 16 is added to the above-described constitution of the thermoelectric conversion device 1B may be adopted.

The heat transfer component 16 is thermally joined to the second end side (the side facing the cold junction side electrode 11b) of each N-type semiconductor layer 6 and each P-type semiconductor layer 7 on a side of a thermoelectric conversion element 5 opposite to a side thereof facing a heat transfer part 10 in a state where the heat transfer component 16 is electrically insulated from the N-type semiconductor layers 6, the P-type semiconductor layers 7, the cold junction side electrode 11b, and the first and second extraction electrodes 12a and 12b with an insulating layer 14b therebetween. Furthermore, the heat transfer component 16 is provided in a state where the heat transfer component 16 is electrically insulated from the second extraction electrode 12b with the insulating layer 14b therebetween on a surface of the thermoelectric conversion element 5 opposite to the substrate 2 side.

The insulating layer 14b is arranged along the outer end surface 5b of the thermoelectric conversion element 5 and a surface of the second extraction electrode 12b facing the heat transfer component 16. In terms of the material of the insulating layer 14b, it is desirable to use a material having high thermal conductivity and capable of electrically insulating the heat transfer component 16 from the N-type semiconductor layers 6, the P-type semiconductor layers 7, the cold junction side electrode 11b, and the second extraction electrode 12b. Examples of such a material can include aluminum oxide (Al₂O₃), aluminum nitride (AlN), or the like. It is desirable that the insulating layer 14b be formed as thin as possible in view of heat conductivity.

The heat transfer component 16 is made of a material with a thermal conductivity higher than the thermal conductivity of air, preferably a material with a thermal conductivity higher than the thermal conductivity of the substrate 2. As such a material of the heat transfer component 16, it is desirable to use a metal, and among these, particularly, for example, aluminum (Al), copper (Cu), or the like which have a high thermal conductivity and which can be easily shaped can be appropriately used. Note that, when the heat transfer component 16 has insulating properties, a constitution in which the above-described insulating layer 14b is omitted may be adopted.

The first extraction electrode 12a is electrically connected to a wiring 13a leading outside of the heat transfer component 16 in a state where the first extraction electrode 12a is electrically insulated from the heat transfer component 16. Furthermore, the second extraction electrode 12b is electrically connected to an external extraction electrode 12c with a wiring 13b leading outside of the heat transfer component 16 therebetween in a state where the second extraction electrode 12b is electrically insulated from the heat transfer component 16.

In the case of such a constitution, since heat transferred to each N-type semiconductor layer 6 and each P-type semiconductor layer 7 is radiated from the second end side (the side facing the cold junction side electrode 11b) to the outside with the heat transfer component 16 therebetween, the second end side (the side facing the cold junction side electrode 11b) of each N-type semiconductor layer 6 and each P-type semiconductor layer 7 can be efficiently cooled.

Therefore, in the thermoelectric conversion device 1C according to the embodiment, a large temperature difference (electromotive force) is generated between: first end sides (the side facing the hot junction side electrode 11a); and the second end sides (the side facing the cold junction side electrode 11b) of each of the N-type semiconductor layers 6 and the P-type semiconductor layers 7. As a result, it is possible to improve an output in the thermoelectric conversion device 1C.

Note that the heat transfer component 16 is not limited to the heat transfer part having the above-described shape and can be appropriately changed to have a shape suitable for heat radiation or cooling. For example, in order to cool the thermoelectric conversion element 5, a constitution in which a heat radiation fin (heat sink) is provided may be adopted. Furthermore, in order to cool the thermoelectric conversion element 5 with water, a constitution in which a flow path through which a cooling liquid is circulated is provided in the heat transfer component 16 may be adopted.

### Fourth Embodiment

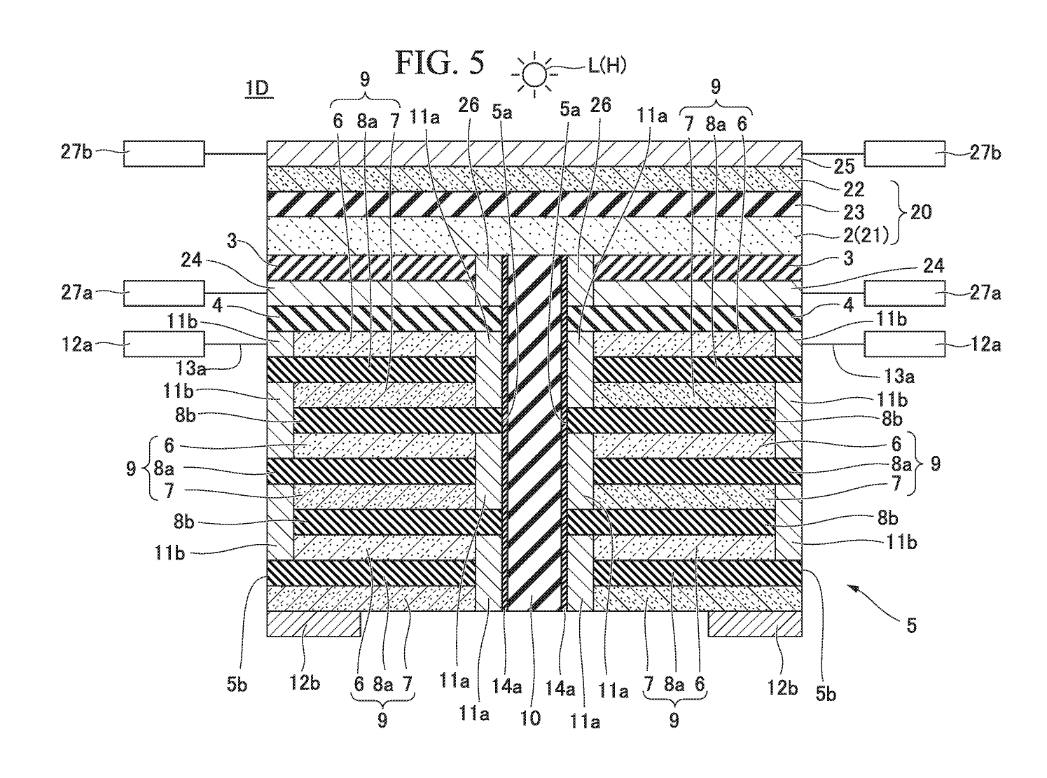

For example, a thermoelectric conversion device 1D illustrated in FIG. 5 will be described below as a fourth embodiment of the disclosure. Note that FIG. 5 is a cross-sectional view showing a schematic constitution of the thermoelectric conversion device 1D. Furthermore, in the following description, constituent elements that are the same as those of the above-described thermoelectric conversion device 1A will be omitted and will be denoted with the same reference numerals in the drawings.

As illustrated in FIG. 5, the thermoelectric conversion device 1D according to the embodiment is configured to include a photoelectric conversion element 20 having a p-type semiconductor layer 21 and an n-type semiconductor layer 22 in addition to the above-described constitution of the thermoelectric conversion device 1A. In other words, the thermoelectric conversion device 1D has a hybrid structure obtained by combining the photoelectric conversion element 20 constituting a photovoltaic cell and the above-described thermoelectric conversion element 5. Note that, although a case in which the photoelectric conversion element 20 is added to the above-described constitution of the thermoelectric conversion device 1A has been exemplified in the embodiment, a constitution in which the photoelectric conversion element 20 is added to the above-described constitution of the thermoelectric conversion device 1B may be adopted.

The photoelectric conversion element 20 has a pin junction structure in which the p-type semiconductor layer 21, the intrinsic semiconductor layer 23, and the n-type semiconductor layer 22 are stacked by providing an intrinsic semiconductor layer 23 between the p-type semiconductor layer 21 and the n-type semiconductor layer 22. Furthermore, the substrate 2 includes one (p-type semiconductor layer 21 in the embodiment) of the p-type semiconductor layer 21 and the n-type semiconductor layer 22, thereby constituting a part of the photoelectric conversion element 20.

For the p-type semiconductor layer 21, for example silicon (Si) doped with boron (B) or aluminum (Al) can be used. For the n-type semiconductor layer 22, for example, silicon (Si) doped with nitrogen (N), phosphorus (P), antimony (As), or antimony (Sb) can be used. For the intrinsic semiconductor layer 23, high purity Si with a specific resistance of 10 Ω·cm or more can be used. Note that, with regard to the photoelectric conversion element 20, the intrinsic semiconductor layer 23 may be omitted and a pn junction structure in which the p-type semiconductor layer 21 and the n-type semiconductor layer 22 are joined may be adopted.

The thermoelectric conversion device 1D includes a lower electrode 24 electrically connected to one (p-type semiconductor layer 21 in the embodiment) of the p-type semiconductor layer 21 and the n-type semiconductor layer 22 constituting the photoelectric conversion element 20 and an upper electrode 25 electrically connected to the second semiconductor layer (n-type semiconductor layer 22 in the embodiment).

The lower electrode 24 is arranged between the first buffer layer 3 (or the air layer 15) and the second buffer layer 4 and electrically connected to the substrate 2 (p-type semiconductor layer 21) with a connection electrode 26 therebetween. Note that examples of conductive materials used for the lower electrode 24 include aluminum (Al) and silver (Ag).

The connection electrode 26 is located between a substrate 1 and the thermoelectric conversion element 5 and electrically connects the substrate 2 (p-type semiconductor layer 21) and the first end side of the lower electrode 24, which are adjacent to each other and sandwich the first buffer layer 3 (or air layer 15), on the side of the connection electrode 26 facing the heat transfer part 10 in a state where the connection electrode 26 is electrically insulated from the heat transfer part 10 with the insulating layer 14a therebetween. Note that examples of a material of the connection electrode 26 include the same materials as for the above-described hot junction side electrode 11a and cold junction side electrode 11b.

The upper electrode 25 is arranged above a surface of the n-type semiconductor layer 22 to be electrically connected to the n-type semiconductor layer 22. Incidentally, transparent conductive materials such as indium tin oxide (ITO) can be used for the upper electrode 25.

The thermoelectric conversion device 1D according to the embodiment includes first extraction electrode 27a electrically connected to the lower electrode 24 and the second extraction electrode 27b electrically connected to the upper electrode 25. The first extraction electrode 27a is electrically connected to the second end side of the lower electrode 24 with a wiring 13c leading to the outside therebetween. The second extraction electrode 27b is electrically connected to an end of the upper electrode 25 with a wiring 13d leading to the outside therebetween.

In the case of such a constitution, the photoelectric conversion element 20 is irradiated with light from an external light source (for example, the sun) L so that an electromotive force (voltage) due to a photovoltaic effect is generated between the lower electrode 24 and the upper electrode 25. Thus, it is possible to convert light energy into electric power and extract the electric power. Furthermore, in the case of such a constitution, the sun can be used as a heat source H of the thermoelectric conversion element 5.

Therefore, in the thermoelectric conversion device 1D according to the embodiment, a hybrid structure in which the above-described thermoelectric conversion devices 1A and 1B are combined with the photoelectric conversion element 20 serving as a photovoltaic cell is adopted so that electric power can be more efficiently extracted using heat from the heat source H or light from a light source L.

In a thermoelectric conversion devices described as the first to fourth embodiment of the disclosure, a heat source is arranged on a base material side so that heat transferred from the heat source to the base material can be efficiently transferred to one end sides (the first end sides) of a P-type semiconductor layer and an N-type semiconductor layer.

Note that the present invention is not necessarily limited to the above-described embodiments and various modifications are possible without departing from the scope of the present invention.

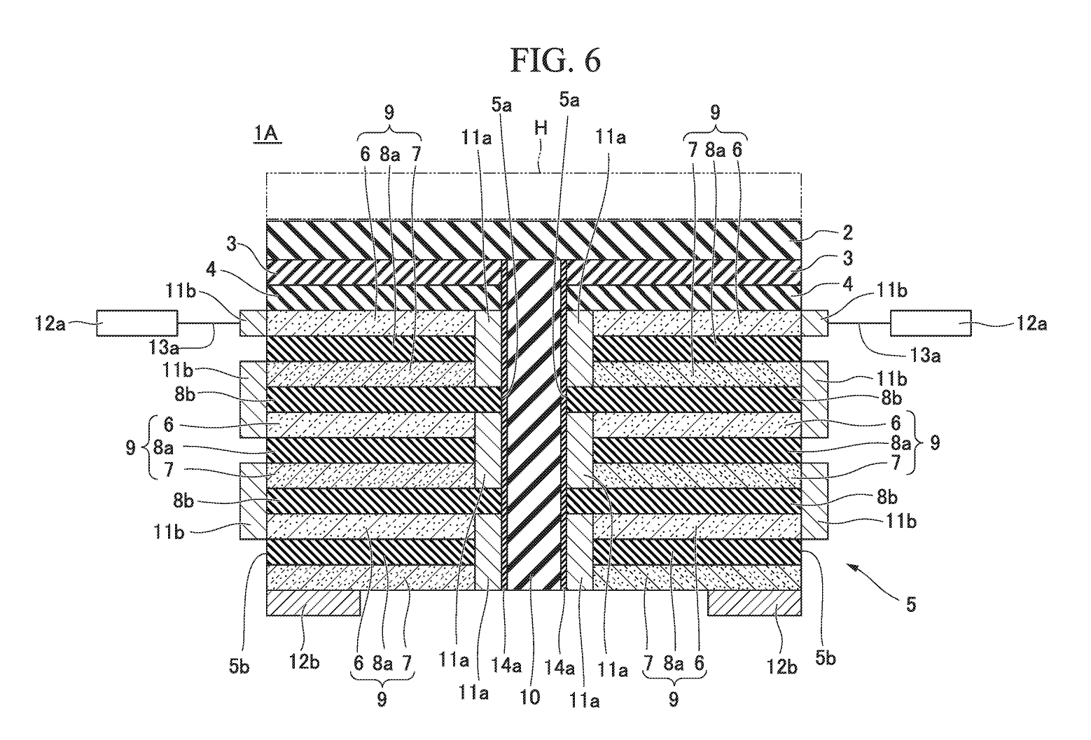

To be specific, although a constitution in which the cold junction side electrode 11b is arranged further inward than a side end surface of the insulating layer 8a on a side of the thermoelectric conversion element 5 opposite to a side thereof facing the heat transfer part 10 is adopted in the thermoelectric conversion devices 1A and 1B illustrated in FIGS. 1 and 3, a constitution in which the second end sides of the N-type semiconductor layers 6 and the P-type semiconductor layers 7 adjacent to each other and sandwiching the insulating layer 8b are electrically connected using the cold junction side electrode 11b arranged further outward than the side end surface of the insulating layer 8a, for example, like in the thermoelectric conversion device 1A illustrated in FIG. 6 can be adopted.

In other words, although a constitution in which the side end surface of the cold junction side electrode 11b is flush with the side end surface of the insulating layer 8a on the side of the thermoelectric conversion element 5 opposite to the side thereof facing the heat transfer part 10 is adopted in the thermoelectric conversion devices 1A and 1B illustrated in FIGS. 1 and 3, a constitution in which the cold junction side electrode 11b is provided to protrude outward from the side end surface of the insulating layer 8a while in contact with the side end surfaces of the N-type semiconductor layers 6, the insulating layer 8b, and the P-type semiconductor layers 7 which are flush with the side end surface of the insulating layer 8a can also be adopted. Note that, although a modification of the thermoelectric conversion device 1A illustrated in FIG. 1 is exemplified in FIG. 6, the same changes can also be performed on the thermoelectric conversion device 1B illustrated in FIG. 3.

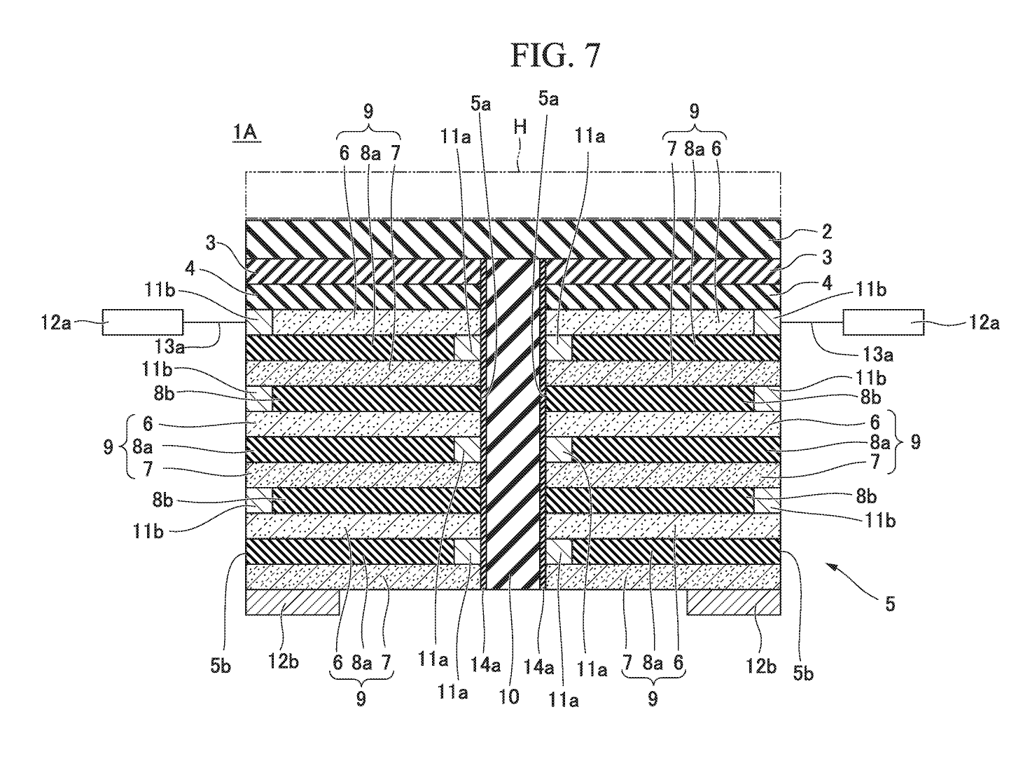

Also, although a constitution in which the hot junction side electrode 11a and the cold junction side electrode 11b are provided along the side end surfaces of the N-type semiconductor layers 6, the insulating layers 8a and 8b, and the P-type semiconductor layers 7 on the first end sides and the second end sides of the N-type semiconductor layers 6 and the P-type semiconductor layers 7, which are adjacent to each other and sandwich the insulating layers 8a and 8b, in the thermoelectric conversion devices 1A and 1B is adopted, the present invention is not limited to such a constitution. In addition, a constitution in which the first end sides and the second end sides of the N-type semiconductor layers 6 and the P-type semiconductor layers 7 adjacent to each other and sandwiching the insulating layers 8a and 8b are electrically connected using the hot junction side electrode 11a and the cold junction side electrode 11b provided along the side end surfaces of the insulating layers 8a and 8b between the N-type semiconductor layers 6 and the P-type semiconductor layers 7, for example, like in the thermoelectric conversion device 1A illustrated in FIG. 7 may be adopted. Note that, although a modification of the thermoelectric conversion device 1A illustrated in FIG. 1 is exemplified in FIG. 7, the same changes can also be performed on the thermoelectric conversion device 1B illustrated in FIG. 3.

Also, the electrical connection with the extraction electrode configured to extract electric power from the thermoelectric conversion element 5 is not limited to the above-described constitution in which the extraction electrodes 12a, 12b, and 12c and the wirings 13a and 13b are provided and appropriate modifications are possible.

Although a constitution in which the first thermoelectric conversion element 5 is provided above the substrate 2 is adopted in the thermoelectric conversion devices 1A and 1B, a constitution in which a plurality of thermoelectric conversion elements 5 are arranged side by side on the first surface side of the substrate 2 can also be adopted.

In the case of such a constitution, a plurality of thermoelectric conversion elements 5 can be collectively formed above the substrate 2 by forming the thin film of the semiconductor material forming the thermoelectric conversion elements 5 above the substrate 2 in which the first and second buffer layers 3 and 4 are provided and then separating the thermoelectric conversion elements 5 adjacent to each other on the surface (for example, by removal using etching).

In addition, a plurality of thermoelectric conversion devices 1A and 1B can also be collectively manufactured at low cost by forming a plurality of thermoelectric conversion elements 5 above the substrate 2 and then cutting the substrate 2 for each thermoelectric conversion element 5.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims

What is claimed is:

1. A thermoelectric conversion device comprising:
a base material;
a thermoelectric conversion element in which an N-type semiconductor layer and a P-type semiconductor layer are stacked on a first surface side of the base material with an insulating layer therebetween; and
a heat transfer part thermally joined to the base material and passing through the thermoelectric conversion element in a thickness direction of the thermoelectric conversion element,
wherein first end sides of the N-type semiconductor layer and the P-type semiconductor layer are thermally joined to the heat transfer part on a side of the thermoelectric conversion element facing the heat transfer part in a state where the N-type semiconductor layer and the P-type semiconductor layer are electrically insulated from the heat transfer part.

2. The thermoelectric conversion device according to claim 1, further comprising:
a first buffer layer or an air layer provided between the base material and the thermoelectric conversion element,
wherein the heat transfer part has a thermal conductivity higher than a thermal conductivity of the first buffer layer or the air layer.

3. The thermoelectric conversion device according to claim 2, further comprising a second buffer layer between the first buffer layer or the air layer and the thermoelectric conversion element.

4. The thermoelectric conversion device according to claim 1, wherein the heat transfer part is provided in a state where the heat transfer part passes through the thermoelectric conversion element inside the thermoelectric conversion element.

5. The thermoelectric conversion device according to claim 2, wherein the heat transfer part is provided in a state where the heat transfer part passes through the thermoelectric conversion element inside the thermoelectric conversion element.

6. The thermoelectric conversion device according to claim 3, wherein the heat transfer part is provided in a state where the heat transfer part passes through the thermoelectric conversion element inside the thermoelectric conversion element.

7. The thermoelectric conversion device according to claim 1, wherein the heat transfer part is provided in a state where the heat transfer part divides the thermoelectric conversion element.

8. The thermoelectric conversion device according to claim 2, wherein the heat transfer part is provided in a state where the heat transfer part divides the thermoelectric conversion element.

9. The thermoelectric conversion device according to claim 3, wherein the heat transfer part is provided in a state where the heat transfer part divides the thermoelectric conversion element.

10. The thermoelectric conversion device according to claim 1,
wherein the thermoelectric conversion element has a structure in which the N-type semiconductor layer and the P-type semiconductor layer are repeatedly stacked with the insulating layer therebetween,
the thermoelectric conversion device further comprises a hot junction side electrode configured to electrically connect the first end sides of the N-type semiconductor layer and the P-type semiconductor layer, which are adjacent to each other and sandwich the insulating layer, on the side of the thermoelectric conversion element facing the heat transfer part: and a cold junction side electrode configured to electrically connect the second end sides of the N-type semiconductor layer and the P-type semiconductor layer, which are adjacent to each other and sandwich the insulating layer, on a side of the thermoelectric conversion element opposite to the side thereof facing the heat transfer part, and
the hot junction side electrode and the cold junction side electrode are arranged to be alternately shifted in a thickness direction of the thermoelectric conversion element so that the N-type semiconductor layer and the P-type semiconductor layer repeatedly stacked with the insulating layer therebetween are configured to be alternately connected in series.

11. The thermoelectric conversion device according to claim 10, further comprising a heat transfer component thermally joined to the second end sides of the N-type semiconductor layer and the P-type semiconductor layer on the side of the thermoelectric conversion element opposite to the side thereof facing the heat transfer part in a state where the heat transfer component is electrically insulated from the N-type semiconductor layer and the P-type semiconductor layer.

12. The thermoelectric conversion device according to claim 1, further comprising:
a photoelectric conversion element that includes a p-type semiconductor layer and an n-type semiconductor layer,
wherein the base material includes one of the p-type semiconductor layer and the n-type semiconductor layer constituting the photoelectric conversion element.

13. The thermoelectric conversion device according to claim 12, further comprising:
a lower electrode electrically connected to one of the p-type semiconductor layer and the n-type semiconductor layer constituting the photoelectric conversion element; and an upper electrode electrically connected to other of the p-type semiconductor layer and the n-type semiconductor layer constituting the photoelectric conversion element.

14. The thermoelectric conversion device according to claim 13, wherein the one of the p-type semiconductor layer and the n-type semiconductor layer constituting the photoelectric conversion element is electrically connected to the lower electrode with a connection electrode provided between the base material and the thermoelectric conversion element.

15. The thermoelectric conversion device according to claim 12, wherein the photoelectric conversion element includes an intrinsic semiconductor layer between the p-type semiconductor layer and the n-type semiconductor layer.
